(19) United States
(12) Patent Application Publication
(10) Pub. No.: US 2005/0287787 A1
(43) Pub. Date: Dec. 29, 2005

(54) Porous ceramic materials as low-k films in semiconductor devices

(76) Inventors: Grant M. Kloster, Lake Oswego, OR (US); Jihperng Leu, Portland, OR (US); Michael D. Goodner, Hillsboro, OR (US); Michael G. Haverty, Mountain View, CA (US); Sadasivan Shankar, Cupertino, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/880,632

(22) Filed: Jun. 29, 2004

(51) Int. Cl. H01L 21/4763; H01L 23/48; H01L 23/52; H01L 29/40

(52) U.S. Cl. 438/618; 438/622; 257/758

(57) ABSTRACT

A method for selecting and forming a low-k, relatively high E porous ceramic film in a semiconductor device is described. A ceramic material is selected having a relatively high Young's modulus and relatively lower dielectric constant. The k is reduced by making the film porous.

### FIELD OF THE INVENTION

The invention relates to the field of dielectric films for semiconductor devices such as integrated circuits.

### PRIOR ART

Several layers of dielectric material are typically used in an integrated circuit. For instance, interconnects are formed between transistors formed in a substrate, with overlying conductors inlaid in an interlayer dielectric (ILD). Often, several such layers are used, each of which includes the conductive lines as well as vias for making contact with conductors in underlying layers. In many cases, the conductors and vias are inlaid in an ILD with a damascene process.

The dielectric constant (k) of the dielectric material to a large degree, determines the capacitance between the various conductors and vias in the integrated circuit. It is desirable to have a low-k dielectric to reduce RC delays and cross-talk between the conductors.

Several dielectrics are used and proposed to be used to reduce this capacitance. One problem with the low-k dielectrics, is that they tend to be mechanically weak. This is particularly a problem since often, chemical mechanical polishing is needed to provide sufficient planarization for the multilayer interconnect structures. This and other stresses can cause a failure in a mechanically weak layer.

### BRIEF DESCRIPTION OF THE DRAWINGS

FIG. 1 is a graph showing the relationship between Young's modulus and the dielectric constant (k) for several materials.

FIG. 2 is a graph illustrating the relationship between Young's modulus and density for several materials including several ceramic materials.

FIG. 3 illustrates a method for an embodiment of the present invention.

FIG. 4A is a cross-sectional, elevation view of an interlayer dielectric (ILD) and an underlying conductor.

FIG. 4B illustrates the layer of FIG. 4A following the etching of a via opening and trench.

FIG. 4C illustrates the structure of FIG. 4B following the formation of a barrier layer.

FIG. 4D illustrates the structure of FIG. 4C following a metalization and planarization process.

FIG. 4E illustrates the structure of FIG. 4D following processing to reduce the density of the ILD.

### DETAILED DESCRIPTION

In the following description, the use and formation of porous ceramic materials in semiconductor devices such as integrated circuits is described. Numerous specific details are set forth, such as specific compounds, in order to provide a thorough understanding of the present invention. It will be apparent to one skilled in the art that these specific details need not be used to practice the present invention. In other instances, well-known processing steps, such as deposition steps, are not described in detail in order not to unnecessarily obscure the present invention.

The mechanical strength of the dielectric layer in a semiconductor device, as mentioned earlier, is important particularly where the layer is subjected to chemical mechanical polishing (CMP) as is often done in a damascene process. Packaging stresses can be even higher than the CMP stresses, and is another particularly important point where the ILD must be resistant to cracking or deforming.

Typically, openings are formed in an ILD for both the vias and conductors in a damascene process. Metal is then deposited or plated into the openings. The metal covers the entire exposed surface of the ILD. A planarization step is used to remove the metal from the surface of the dielectric, most effectively with polishing. Unless the ILD is strong enough to withstand this polishing and other stresses, defects in the device can result. The other stresses include those associated with packaging and thermal cycling during ordinary use.

Generally, the mechanical strength of a dielectric material includes, but is not limited to, its elastic modulus, hardness and cohesive strength. For the most part, the mechanical strength tracks well with the elastic modulus, and consequently, for purposes of this patent, the elastic modulus, also referred to as Young's modulus, is used to evaluate mechanical strength. Young's modulus is defined as the stress-over-strain for a given material and is generally measured in giga-Pascals (GPa). This modulus varies from less than 0.1 for rubber, 3-5 for polyimides, 100 or less for soft metals, the mid-hundreds for many ceramics, to 1,000 for diamond.

As mentioned, a dielectric layer including the ILD should have a low-k when used in an integrated circuit, particularly when operating at a high frequency as do most modern circuits. A k of approximately 2.2 or lower is considered to be an acceptable dielectric constant for such circuits fabricated at a minimum pitch of around 32 nm. (The dielectric constant may be as high as 2.4 and still considered acceptable, consequently as used in this patent, “approximately 2.2” is intended to cover the upper range of k=2.4.) An acceptable mechanical strength, as measured by Young's modulus, for integrated circuit processing is considered to be 6 GPa or higher, preferably about 10 GPa or higher.

As described below in more detail, ceramic materials having in their dense matrix state (non-porous) a k greater than 2.2 are used as an ILD in a porous matrix. The k is lowered by reducing the density of the ceramic material. This is done by making the ceramic material porous while still maintaining sufficient mechanical strength. These materials have E values in excess of 6 GPa in the porous matrix, as will be discussed.

In general, ceramics are considered to be non-metallic materials that are strong and brittle. They are typically electric insulators, resistant to heat and often not easily attacked by chemicals. The ceramic films including those with nitrides, may be formed by several processes including using commercially available precursors, as will be described later.

As the density of a dielectric material decreases (increased porosity), its k decreases proportionally. The strength of the material as its density decreases is predicted by the formula: E=E⁰(ρ^{m}), where E=predicted Young's modulus, E₀=Young's modulus of a dense matrix (original material before the material is made porous), ρ=density (proportional to porosity and k), and m=experimentally determined exponent.

By way of example, the calculated Young's modulus for CDO with k=2.2 (15% carbon, 30% porosity) is 4.1 GPa. By contrast, the calculated Young's modulus for porous SiO₂ with k=2.2 (47% porosity) is 8.2 GPa.

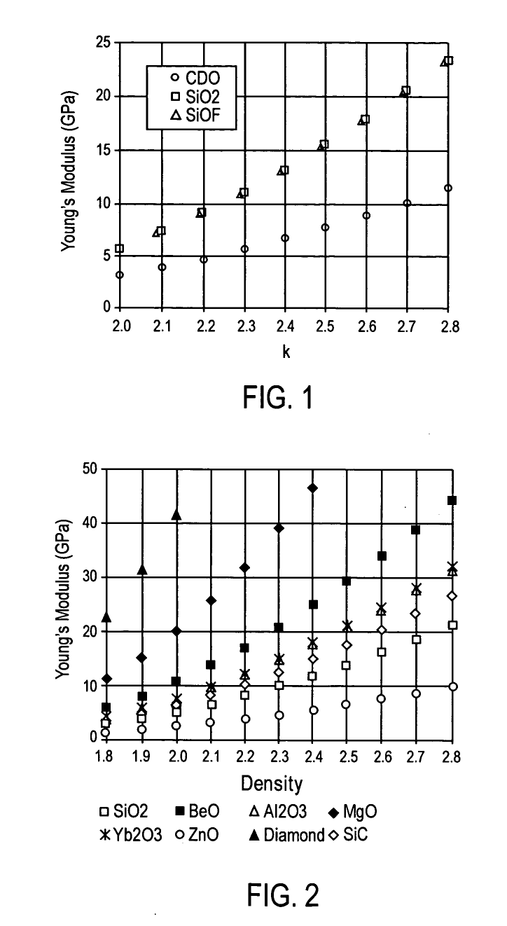

FIG. 1 illustrates the k values versus Young's modulus for three silicon dioxide (non-ceramic) based materials. As can be seen for a k of 2.2, these materials fall below or marginally meet an E of 6 GPa or greater, the minimum E sought.

FIG. 2 illustrate the Young's modulus for several ceramic materials as a function of the material's density. For purposes of comparison, this graph also illustrates silicon dioxide and diamond. Bearing in mind that k is also proportional to density, it can be seen that several of these ceramic materials possess greater strength at lower densities than silicon dioxide. In fact, there are several ceramic materials that have a higher Young's modulus than SiO₂ at porosities needed for a k=2.2.

Assume that a k of 2.2 is needed for a dielectric film. The table below identifies several ceramic materials, their initial k and E₀ (dense film) and their porosity and E for a k of 2.2. Silicon dioxide is also shown in the table for purposes of comparison.

TABLE 1
(k = 2.2)

| | |
|---|---|
| | Porous Film |
| Dense Film | Calculations |

| Ceramic | k | E₀(GPa) | Porosity (%) | E (GPa) |
|---|---|---|---|---|
| SiO₂ | 4.5 | 75 | 47 | 8.2 |
| BeO | 7.4 | 357 | 56 | 19.7 |
| MgO | 9.7 | 290 | 62 | 10.2 |
| Al₂O₃ | 9.7 | 400 | 62 | 14.1 |
| Yb₂O₃ | 5.0 | 139 | 50 | 12.3 |
| SiC | 5.5 | 430 | 52 | 32.0 |
| Si₃N₄ | 7.5 | 310 | 58 | 14.6 |
| AIN | 8.8 | 345 | 60 | 13.4 |

Consequently, porous BeO, MgO, Al₂O₃, Yb₂O₃, SiC, Si₃N₄, and AlN provide a better performing film than SiO₂ since they are all stronger than SiO₂ for a porosity that provides a k of 2.2.

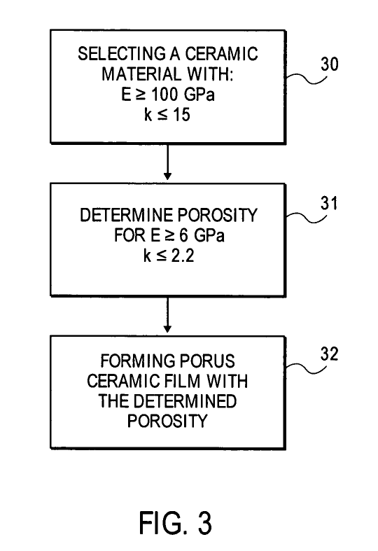

To provide a ceramic film for use in a semiconductor device, a selection is first made of a ceramic material with an E₀ greater than or equal to 100 GPa. The k of the film should be 15 or less. This is shown as 30 in FIG. 3. Then, a determination is made of the porosity needed for the desired k, for instance, a k of approximately 2.2 or less. This results in an E of 6 GPa or more, as shown at 31 of FIG. 3. Now, as shown at 32, the porous ceramic film is formed with a determined porosity, thereby providing the desired k. This is what is shown in Table 1 for the illustrated ceramic materials.

Plasma enhanced chemical vapor deposition (PECVD) of ceramic films is well-known. For example, zirconium tert-butoxide is used to deposit zirconium dioxide films with k=16 (see Byeong-Ok Cho, B.-O., et al., Appl. Phys. Lett., 80(16), 2002, 1052-1054). A precursor may be used for the deposition of the film such as Al(OC(CH3)₄)₄ for Al₂O₃, by PECVD, spin-on, or other conventional deposition techniques. Other precursors to deposit ceramic materials which are commercially available can be chosen from metal alkoxides (OR), acetates (OAc), acetonyl acetates, and hexafluoroacetonylacetates. Metal alkyl or olefin species also can be used if an oxidant such as O₂ or N₂O are added to the plasma. Nitrides are generally formed by adding ammonia or amines to the plasma.

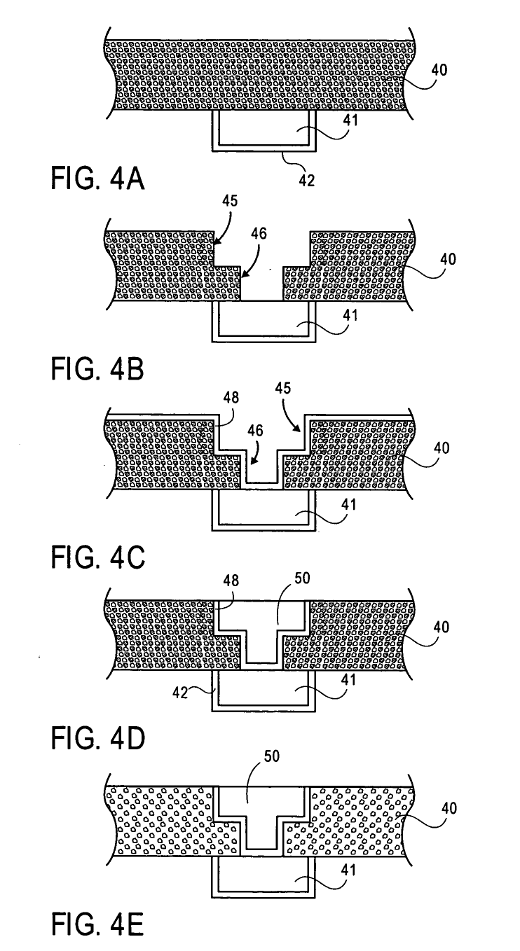

Pore generating can be added by incorporating a carbon-based polymer in the film, by adding ethylene to the plasma, for example. The carbon based porogen can be removed at a later down-stream process step. For instance, the porogen can be thermally decomposed immediately after deposition, or even later after CMP processing to avoid etching porous materials in a damascene process, as will be described in conjunction with FIGS. 4A through 4E. A porogen can be decomposed in several other ways, for instance, by plasma exposure, electron-beam treatment, wet etching, using super-critical CO₂, ultra-violet or infrared radiation, microwaves or other post-deposition treatment as is appropriate for the particular porogen.

Porogen may be incorporated in the film by adding a second polymerizable component to the deposition plasma. Alternatively, side chains attached to the precursor can be used that survive plasma deposition and that can be decomposed after deposition.

The porosity of the deposited film may also be obtained by increasing the deposition rate to produce a low-film density, for instance, by adding more oxidant to the plasma. This however, results in the immediate formation of the low-density porous film.

Several processes for forming low-density films are described in U.S. Patent publication number 20040026783 Al, published Feb. 12, 2004, entitled “Low-k Dielectric Film with Good Mechanical Strength”; U.S. Pat. No. application Ser. No. 10/377,061, filed Feb. 28, 2003, entitled “Forming a Dielectric Layer Using A Hydrocarbon-Containing Precursor”; U.S. patent application Ser. No. 10/394,104, filed Mar. 21, 2003, entitled “Forming a Dielectric Layer Using Porogens”; and U.S. patent application Ser. No. 10/746,485, filed Dec. 23, 2003, entitled “Method and Materials for Self-Aligned Dual Damascene Interconnect Structure.”

Referring now to FIG. 4A, an ILD 40 comprising a ceramic material and a porogen is shown formed on an underlying layer where only a single conductor 41 and a surrounding barrier layer of the underlying layer is illustrated. The ILD 40 may be any of the materials shown in Table 1, mixed with a porogen so that the final porosity of the ILD 40 is as shown in Table 1 for the corresponding ceramic material. Note that in FIG. 4A, the film has been deposited with the porogen, and consequently, it will have more strength than a film that, for instance, is deposited at a higher deposition rate, so as to be porous on initial deposition.

Now, as shown in FIG. 4B, openings are etched into the layer 40, for instance, a via opening 46 and a trench 45 are etched above the conductor 41. An etchant stop layer or hard mask layer which is sometimes used to prevent over-etching may be used, but not illustrated in the figures.

Following the formation of the openings, a barrier metal 48 is formed to line the openings as is typically done in a damascene process. As shown in FIG. 4C, tantalum or a tantalum alloy is often used as the barrier metal. This layer may not be required if the subsequently formed metal does not diffuse into the selected ceramic material.

Then, a conductor such as copper or a copper alloy is plated onto the barrier layer 48, in an ordinary plating process. The plated metal also covers the upper surface of the layer 40 and is removed from that surface using CMP. The resultant structure is shown in FIG. 4D, where for instance, copper 50 fills the trench and via opening, and is separated from the layer 40 by the barrier material 48. In this way, the conductor 50 is in contract with the conductor 41.

Now as shown in FIG. 4E, the porogen is removed so as to make the ILD 40 porous. The resultant layer 40 then will have a k of approximately 2.2, and a porosity and final E value as shown in Table 1 for a ceramic material selected from that table. The porogen may be removed in one of numerous ways as described above.

Thus, the use of a ceramic material for a low-k, relatively high E layer has been described.

1. A method comprising:
selecting a ceramic material having a Young's modulus (E) of 100 GPa or greater and a dielectric constant (k) of 15 or less;
determining the porosity of the material needed for an E of 6 GPa or greater, and a k of approximately 2.2 or less; and
forming a layer of the material in a semiconductor device, having the determined porosity.

2. The method defined by claim 1, wherein the material is selected from the group of BeO, MgO, Al₂O₃, Yb₂O₃, SiC, Si₃N₄ and AlN.

3. The method defined by claim 1, wherein the forming of the layer comprises:
depositing the material as a interlayer dielectric (ILD) in an integrated circuit;
inlaying conductors in the ILD using a damascene process; and
removing the porogen to provide the determined porosity.

4. The method defined by claim 2, wherein the forming of the layer comprises:
depositing the material as a interlayer dielectric (ILD) in an integrated circuit;
inlaying conductors in the ILD using a damascene process; and
removing the porogen to provide the determined porosity.

5. The method defined by claim 1, wherein the forming the layer comprises depositing of the material at a sufficiently high deposition rate to produce a film of the determined porosity.

6. The method defined by claim 5, wherein the deposition occurs in a plasma enhanced chemical vapor deposition process, and the increase deposition rate is achieved by adding more oxidant to the plasma.

7. The method defined by claim 1, wherein the forming the layer comprises forming an ILD in an integrated circuit with the determined porosity, and then inlaying within the layer conductors with a damascene process.

8. The method defined by claim 7, wherein the forming of the layer comprises the formation of the layer with a porogen and removal of the porogen.

9. The method defined by claim 7, wherein the formation of the layer comprises depositing the layer at a sufficiently high rate to produce a film having the determined porosity.

10-14. (canceled)

15. An integrated circuit including:
a porous ceramic layer, the ceramic material in a non-porous state having a Young's modulus (E) of 100 or greater GPa and a dielectric constant of 15 or less, the porous ceramic layer having an E of 6 or greater GPa, and a dielectric constant of approximately 2.2 or less.

16. The integrated circuit of claim 15, wherein the ceramic material is selected from the group of BeO, MgO, Al₂O₃, Yb₂O₃, SiC, Si₃N₄, and AlN.

17. The integrated circuit of claim 16, wherein the layer is an interlayer dielectric (ILD) and includes conductors formed with a damascene process.

18. An interlayer dielectric (ILD) in a semiconductor device comprising:
a porous ceramic material selected from the group of BeO, MgO, Al₂O₃, Yb₂O₃, SiC, Si₃N₄, and AlN, having a dielectric constant of approximately 2.2 or less and a Young's modulus of 6 GPa or more.

19. The ILD of claim 18, wherein the ceramic material in its non-porous state has an E of 100 GPa or greater, and a k or 15 or less.

20. The ILD of claim 19, wherein conductors are inlaid within the ILD.
